(19) United States
(12) Patent Application Publication
(10) Pub. No.: US 2026/0211550 A1
(43) Pub. Date: Jul. 23, 2026

(54) MEMORY SYSTEM AND METHOD OF CONTROLLING NON-VOLATILE MEMORY

(71) Applicant: Kioxia Corporation, Tokyo (JP)

(72) Inventor: Shingo YANAGAWA, Kawasaki Kanagawa (JP)

(73) Assignee: Kioxia Corporation, Tokyo (JP)

(21) Appl. No.: 19/328,244

(22) Filed: Sep. 15, 2025

(30) Foreign Application Priority Data
Jan. 23, 2025 (JP) 2025-009516

(51) Int. Cl. G06F 3/06; G06F 12/02

(52) U.S. Cl. CPC G06F 3/0604; G06F 3/0659; G06F 12/0246

(57) ABSTRACT

A memory system includes a non-volatile memory and a control circuit electrically connected to the non-volatile memory. The control circuit is configured to, upon reception of a first read request issued from a host during a current write operation, determine a first ratio of a first duration to a second duration, the first duration being an accumulated time of one or more read operations executed subsequent to completion of a most recently completed write operation and prior to completion of the current write operation, the second duration being a required time for the current write operation; and determine whether to suspend the current write operation based on the first ratio.

### CROSS-REFERENCE TO RELATED APPLICATION

This application is based upon and claims the benefit of priority from Japanese Patent Application No. 2025-009516, filed Jan. 23, 2025, the entire contents of which are incorporated herein by reference.

### FIELD

Embodiments described herein relate generally to a memory system and a method of controlling a non-volatile memory.

### BACKGROUND

In recent years, memory systems that include non-volatile memories have become widespread. As one of such memory systems, a solid state drive (SSD) that includes NAND flash memories has been known.

SSDs have been used as storage devices of various host computer systems, such as servers in a data center.

For storage devices, such as SSDs, a new technology to flexibly control access to non-volatile memories is required to be achieved.

### BRIEF DESCRIPTION OF THE DRAWINGS

FIG. 1 is a block diagram for illustrating an example of a memory system according to an embodiment.

FIG. 2 is a block diagram for illustrating an example of a configuration of a coordinator according to the embodiment.

FIG. 3 is a diagram for illustrating an example of coordination of a read performance and a write performance by the coordinator according to the embodiment.

FIG. 4 is a diagram for illustrating another example of coordination by the coordinator according to the embodiment.

FIG. 5 is a flowchart for illustrating an example of a procedure of determining a write die time by the coordinator according to the embodiment.

FIG. 6 is a flowchart for illustrating an example of a procedure of determining a read die time by the coordinator according to the embodiment.

FIG. 7 is a flowchart for illustrating an example of a procedure of determining whether the coordinator according to the embodiment applies a write suspend function.

FIG. 8 is a flowchart for illustrating an example of a procedure of write suspend by the coordinator according to the embodiment.

### DETAILED DESCRIPTION

An embodiment of the present invention intends to provide a memory system that can flexibly control access to a non-volatile memory.

In general, according to one embodiment, the memory system includes a non-volatile memory and a control circuit electrically connected to the non-volatile memory. The control circuit is configured to, upon reception of a first read request issued from a host during a current write operation, determine a first ratio of a first duration to a second duration, the first duration being an accumulated time of one or more read operations executed subsequent to completion of a most recently completed write operation and prior to completion of the current write operation, the second duration being a required time for the current write operation; and determine whether to suspend the current write operation based on the first ratio.

An embodiment is described below with reference to the drawings. The following description is for exemplifying a device and a method for implementing a technical thought of the embodiment. The technical thought of the embodiment is not limited to the structure, shape, arrangement, material or the like of each configuration element described below. Modifications easily conceivable by those skilled in the art are naturally encompassed by the scope of the disclosure. To make the description clearer, in the drawings, the size, thickness, planar dimension, shape or the like of each element is changed from that of an actual element and is schematically represented in some cases. Among the drawings, elements with different dimensional relationships or different ratios between them are included in some cases. Among the drawings, corresponding elements are assigned the same reference numeral, and redundant description is omitted in some cases. Some elements are each assigned a plurality of names in some cases. Examples of these names are given only illustrative examples, without preventing these elements from being assigned another name. An element that is not assigned a plurality of names is not prevented from being assigned another name. Connection indicates not only direct connection but also connection via another element. In the case of not clearly representing that the number of elements is plural, the element is provided as a single element or a plurality of elements.

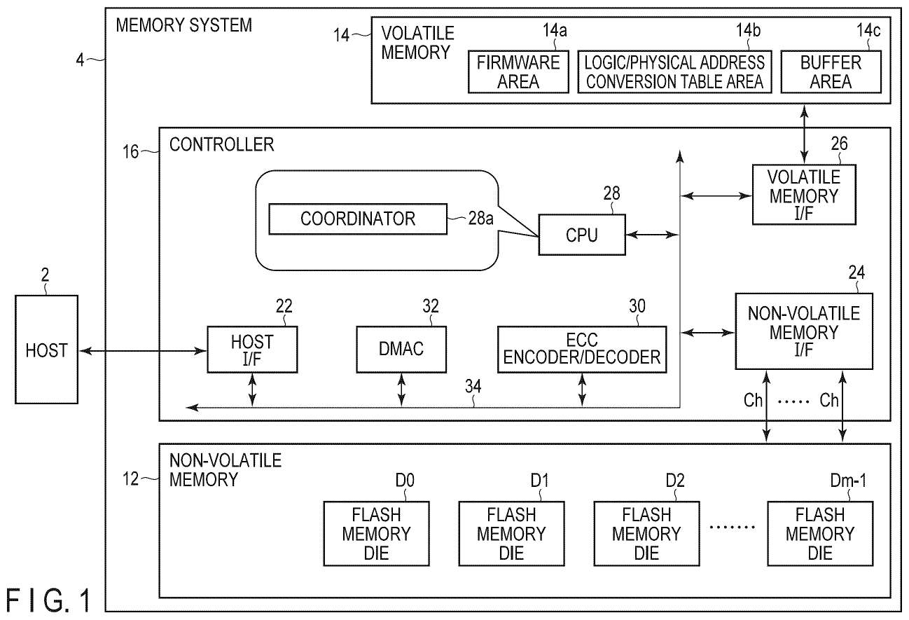

FIG. 1 is a block diagram for illustrating an example of a memory system 4 according to the embodiment. The memory system 4 is capable of being electrically connected to a host 2. The host 2 may be a storage server that stores a large amount and various data items in the memory system 4, or a server or a personal computer.

The memory system 4 is a semiconductor storage device configured to write data into a non-volatile memory and read data from the non-volatile memory. An example of the memory system 4 is an SSD. An example of the non-volatile memory is a NAND flash memory. The memory system 4 can be used as a storage of the host 2. The memory system 4 may be internally included in the host 2, or be connected to the host 2 via a cable or a network.

The memory system 4 includes a non-volatile memory 12, a volatile memory 14, and a controller 16.

An example of the non-volatile memory 12 is a NAND flash memory. In the present application, the non-volatile memory 12 is also called a NAND flash memory 12. The NAND flash memory 12 includes a memory cell array that includes a plurality of memory cells arranged in a matrix manner. Each memory cell stores data in a non-volatile manner in accordance with a threshold voltage. The NAND flash memory 12 may be a flash memory that has a two-dimensional structure, or a flash memory that has a three-dimensional structure.

The memory cell array of the NAND flash memory 12 includes a plurality of blocks. Each of the blocks includes a plurality of pages. The block functions as a minimum unit of a data erase operation. The data erase operation is an operation that erases (or initializes) data stored in a memory cell included in a block to be erased, by setting the threshold voltage of the memory cell to a predetermined voltage or lower. The block is sometimes called an erase block or a physical block. Each of the pages includes a plurality of memory cells commonly connected to a single word line. The page functions as a unit of a write operation and a read operation. The word line may function as a unit of a write operation and a read operation.

An example of the volatile memory 14 is a dynamic random access memory (DRAM) or a static random access memory (SRAM), or both of them. In the present application, the volatile memory 14 is also called a DRAM 14. The DRAM 14 may be provided with a firmware area 14a, a logical/physical address conversion table area 14b, and a buffer area 14c. The buffer area 14c is an area for temporarily storing data.

Firmware is a control program that includes a group of instructions for causing a CPU 28 to execute various processes. The CPU 28 controls the operations of the controller 16 by executing the firmware. The firmware may be read from the NAND flash memory 12 or a read-only memory (ROM), not shown, when the memory system 4 is activated, and be stored in the firmware area 14a.

A logical/physical address conversion table includes a lookup table (LUT). The LUT manages mapping between a data identifier for identifying data to be accessed, and a physical address of the NAND flash memory 12. An example of the data identifier is a logical address used by the host 2 to designate the address of a storage area of the memory system 4. An example of the logical address is a logical block address (LBA). The physical address is represented by a block address indicating a write destination block, and an offset in the block that indicates a position in the write destination block. The block address is a block identifier for identifying one specific block among the blocks included in the NAND flash memory 12.

The logical/physical address conversion table may be read from the NAND flash memory 12 when the memory system 4 is activated, and be stored in the area 14b. The logical/physical address conversion table stored in the area 14b may be written into the NAND flash memory 12 at an appropriate time point during the operation of the memory system 4.

The CPU 28 can recognize a physical storage position of data in the NAND flash memory 12, using the logical/physical address conversion table.

The buffer area 14c includes: a write buffer for temporarily storing data to be written into the NAND flash memory 12; and a read buffer for temporarily storing data read from the NAND flash memory 12.

The controller 16 functions as a memory controller configured to control the NAND flash memory 12. The controller 16 is configured as, for example, a system-on-a-chip (SoC).

The writing of data into one page of the NAND flash memory 12 can be performed only once per program/erase cycle. Accordingly, the controller 16 writes updated data corresponding to a certain logical address, not into a physical storage position where previous data corresponding to this logical address is stored, but into another physical storage position. The controller 16 updates the logical/physical address conversion table so as to associate this logical address with said another physical storage position. Thus, the controller 16 invalidates the previous data. Data referred to by the logical/physical address conversion table, i.e., data associated with a logical address is called valid data. Data associated with no logical address is called invalid data. The valid data is data that is possibly requested to be read later by the host 2. The invalid data is data that is not possibly requested to be read by the host 2.

The controller 16 includes a host interface circuit (host I/F) 22, a non-volatile memory interface circuit (non-volatile memory I/F) 24, a volatile memory interface circuit (volatile memory I/F) 26, a CPU 28, an error correction code encoder/decoder (ECC encoder/decoder) 30, and a direct memory access controller (DMAC) 32. These host I/F 22, non-volatile memory I/F 24, volatile memory I/F 26, CPU 28, ECC encoder/decoder 30, and DMAC 46 may be connected to each other via a bus 34.

The host I/F 22 functions as a circuit that receives various requests and data items from the host 2. The host I/F 22 is, for example, a PCIe controller. In a configuration where the memory system 4 is connected to the host 2 via the Ethernet™, the host I/F 22 may be an NVMe over Fablics™ (NVMeOF™) controller.

The host I/F 22 receives various requests and data items from the host 2. The host I/F 22 transfers the received requests and data items to one of the non-volatile memory I/F 24, the volatile memory I/F 26, and the CPU 28.

An example of the request is a write request or a read request. The write request is a request for writing data into the NAND flash memory 12. The write request designates, for example, an LBA corresponding to write data, the length of the write data, and a buffer address that indicates a position in a memory of the host 2 where the write data is stored. The read request is a request for reading data from the NAND flash memory 12. The read request designates, for example, an LBA corresponding to read data, the length of the read data, and a buffer address that indicates a position in the memory of the host 2 to which the read data is to be transferred.

The host I/F 22 functions also as a circuit that transmits, to the host 2, a response and data corresponding to the request. An example of the response is a write completion response, or a read completion response. The host I/F 22 receives a response and data to be transmitted, from one of the non-volatile memory I/F 24, the volatile memory I/F 26, and the CPU 28.

The non-volatile memory I/F 24 electrically connects the controller 16 and the NAND flash memory 12 to each other. The non-volatile memory I/F 24 conforms to an interface standard, such as Toggle DDR, Open NAND Flash Interface (ONFI) or the like.

The non-volatile memory I/F 24 functions as a NAND control circuit configured to control the NAND flash memory 12.

The volatile memory I/F 26 functions as a DRAM control circuit configured to control access to the DRAM 14.

The CPU 28 is a processor configured to control the host I/F 22, the non-volatile memory I/F 24, the volatile memory I/F 26, and the ECC encoder/decoder 30. The CPU 28 performs various processes by executing firmware loaded into the DRAM 14. The CPU 28 can execute command processing and the like for processing various requests issued by the host 2. The operation of the CPU 28 is controlled by the firmware executed by the CPU 28.

Upon reception of a request issued by the host 2, the CPU 28 generates a command that is to be transmitted to the NAND flash memory 12 in order to achieve the request. The CPU 28 transmits the command to the NAND flash memory 12 via the non-volatile memory I/F 24. The NAND flash memory 12 operates according to the command, and transmits a completion response to the CPU 28 via the non-volatile memory I/F 24 when the command is completed.

The CPU 28 may function as a coordinator 28a that coordinates the read performance and the write performance of the memory system 4 by, for example, selectively suspending a write operation based on an accumulated execution time, or ‘die time,’ for prior read and write operations. The coordinator 28a may be implemented by the CPU 28 executing firmware. The details of the coordinator 28a are described later.

When data is written into the NAND flash memory 12, the ECC encoder/decoder 30 encodes the data, thereby adding error correction code (ECC) as redundancy code to the data. When data is read from the NAND flash memory 12, the ECC encoder/decoder 30 performs error correction for the data, using the ECC added to the read data.

The DMAC 32 is a circuit that executes direct memory access (DMA). Under control by the CPU 28, the DMAC 32 executes data transfer between the memory, not shown, of the host 2, and the DRAM 14.

The function of each component in the controller 16 may be achieved by dedicated hardware in the controller 16, achieved by the CPU 28 executing firmware, or achieved by a combination thereof.

The NAND flash memory 12 may include a plurality of NAND flash memory dies D0, D1, D2, . . . , Dm-1. In FIG. 1, the NAND flash memory dies are simply called flash memory dies D0, D1, D2, . . . , Dm-1. In the present application, an unspecified NAND flash memory die among the NAND flash memory dies is sometimes called a NAND flash memory die D. Each individual NAND flash memory die D can independently operate. Each NAND flash memory die D functions as a unit that can operate in parallel. Note that the NAND flash memory die D may have a multi-plane configuration. In this case, each plane of the NAND flash memory die D functions as a unit that can operate in parallel.

In the case where the NAND flash memory 12 includes a plurality of NAND flash memory dies D, a block address indicating a write destination block is represented by a combination of a die identifier and a block identifier. In the case where the NAND flash memory die D includes a plurality of planes, a block address is represented by a combination of a die identifier, a plane identifier, and a block identifier.

The process of the coordinator 28a is described.

The workload assumed by a customer of the memory system, who is a user of the host (e.g., data center), is complicated. Some of memory systems have a write suspend function in order to coordinate the read performance and the write performance.

The read performance is represented by the read operation time of the memory system. The write performance is represented by the write operation time of the memory system. The read operation includes a command generating operation, a sense operation, and a data-out operation. The sense operation is an operation of the NAND flash memory 12 sensing data in the memory cell. The data-out operation is an operation of transferring the sensed data from the NAND flash memory 12 to the controller 16. Commands pertaining to the read operation include a sense command and a data-out command. Write operations include a command generating operation, data-in operation, and a program operation. The data-in operation is an operation of transferring write data from the controller 16 to the NAND flash memory 12. The program operation is an operation by the NAND flash memory 12 programming the write data into the memory cell. Commands pertaining to the write operation include a data-in command and a program command.

The coordination of the read performance and the write performance of the memory system is performed by adjusting the ratio of the read operation time to the write operation time. Hereinafter, the ratio of the read operation time to the write operation time is also called a W/R ratio.

The write operation time for one write request is sometimes several to several tens of times longer than the read operation time for one read request. Accordingly, when the memory system receives a read request during execution of the write operation, start of the read operation that is delayed until the completion of the write operation increases the time after reception of the read request until completion of the read operation. That is, the response performance of the memory system to the read request is significantly degraded.

A write suspend function suspends an ongoing write operation executed by the memory system upon reception of a read request, executes a read operation during the suspension, and resumes the suspended write operation in response to the completion of the read operation. This improves the response performance of the memory system to the read request. The write suspend function is sometimes called a suspend read function.

However, when the host transmits an unthrottled job to the memory system, the read performance and the write performance of the memory system change depending on the workload and the internal state of the memory system. In this case, there is a possibility that a simple write suspend function cannot meet customer demands pertaining to the read performance and the write performance of the memory system. For example, even a memory system that has the write suspend function may process only write requests or only read requests in some cases.

A throttled job is a job that is throttled by the host at a rate allowing the memory system to respond. An unthrottled job is a job that is not throttled by the host. A request that the host inputs into a submission queue without consideration of the read performance and the write performance of the memory system is an unthrottled job.

An example of a workload that affects the read performance and the write performance of the memory system is the configuration of the submission queue, or the size of data accompanying the request.

Examples of the internal state of the memory system that affects the read performance and the write performance of the memory system include the condition of suspension of the write operation, the configurations of a read buffer and a write buffer, or the over-provisioning ratio of the NAND flash memory.

The memory system can execute a compaction (garbage collection) operation. The compaction is an operation for reducing the number of active blocks in which valid data and invalid data are mixedly present, and increasing the number of free blocks. The active block is a block that includes at least one valid data item. The free block is a block that includes no valid data item, and only includes invalid data items. The free block can be used as a write destination block for new data after an erase operation. The compaction operation includes an operation of reading valid data from an active block (compaction read operation), and an operation of writing valid data into another block (compaction write operation). The compaction operation makes the active block transition to a free block.

The read operation and the write operation of the NAND flash memory include operations due to compaction operations besides operations due to a read request and a write request issued by the host. In a case where the over-provisioning ratio is low, the execution frequency of the compaction operation is high. In this case, an operation due to a request issued by the host, and an operation due to a compaction operation tend to collide with each other. That is, the over-provisioning ratio affects the read performance and the write performance of the memory system.

Customers sometimes intend to designate the W/R ratio of the memory system. To meet this demand, it is conceivable to adopt a concept of die time fairness. The die time fairness is adjustment of each operation time to make the W/R ratio of each flash memory die D of the NAND flash memory have a desired value. In the present application, the cumulative total of the read operation time of each flash memory die D is called a read die time. The cumulative total of the write operation time of each flash memory die D is called a write die time.

In a case where both the read request and the write request are stored in the submission queue, the fetch operation for the read request and the fetch operation for the write request from the submission queue are coordinated, thereby allowing the W/R ratio to be adjusted to meet the customer demands. However, where only one of the read request and the write request is stored in the submission queue, there is no alternative but to execute an operation pertaining to the stored request. Accordingly, the adjustment of the fetch operations cannot adjust the W/R ratio. To make the W/R ratio adjustable, the execution of the operation pertaining to a request (in particular, the fetch operation) is waited until both a read request and a write request are stored in the submission queue. However, it is not preferable because this degrades the latency of the memory system.

To make the W/R ratio adjustable, a buffer memory having a large size is required to be provided in the memory system such that the timing of command transmission to the NAND flash memory can be adjusted in a state where read requests and write requests are stored in the submission queue with a queue depth deeper than that for the read and write performances of the NAND flash memory. However, it is not preferable to provide a buffer memory having a large size.

The memory system 4 according to the embodiment determines (1) the timing of performing addition of the read operation time, and the timing of addition of the write operation time, (2) the timing of determining which is longer between the read die time and the write die time, (3) the condition for suspending the write operation, (4) the condition for resuming the write operation, and the like, thereby adjusting the read operation and the write operation of the memory system 4 so as to meet the customer demands.

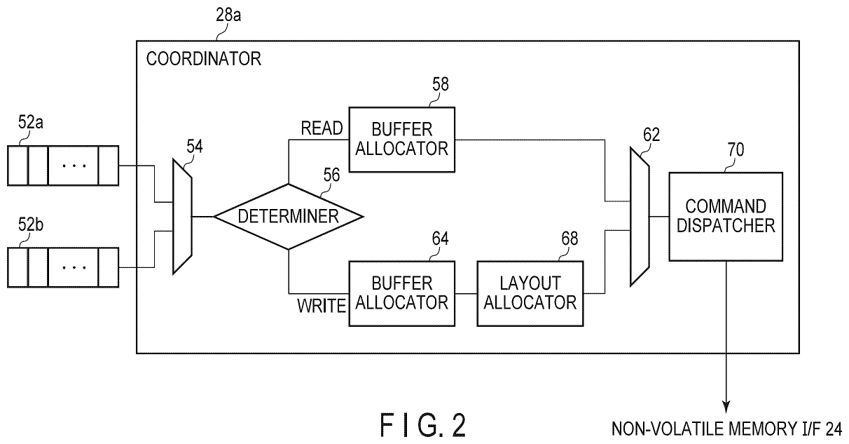

FIG. 2 is a diagram for illustrating an example of the configuration of the coordinator 28a. The coordinator 28a includes a selector 54, a determiner 56, a buffer allocator 58, a buffer allocator 64, a layout allocator 68, a selector 62, and a command dispatcher 70. The functions of these components may be achieved by the CPU 28 performing firmware, by dedicated hardware in the controller 16, or by a combination thereof.

The host 2 writes a request into a submission queue 52. The request is, for example, an unthrottled job. The output of the submission queue 52 is input into the coordinator 28a. In the example shown in FIG. 2, the submission queue includes a submission queue 52a for read requests, and a submission queue 52b for write requests. Alternatively, read requests and write requests may be mixedly written in a single queue.

The read request output from the submission queue 52a and the write request output from the submission queue 52b are input into the determiner 56 via the selector 54, which has two inputs and one output. Note that the requests input into the determiner 56 may include a request generated in the memory system 4, such as a request for a compaction read operation (compaction read request). In this case, the selector 54 is made up of a selector with three inputs and one output, and a request generated in the memory system 4 is also input into the selector 54.

The determiner 56 determines whether the request input from the selector 54 is the read request or the write request.

The read request is input into the buffer allocator 58 from the determiner 56. The buffer allocator 58 allocates the read buffer in the buffer area 14c in response to the read request. Based on the LBA included in the read request, a read target physical address is output from a logical/physical address conversion table 60 stored in the logical/physical address conversion table area 14b. Read command generation information that includes at least the read request, identification information on the read buffer, and the read target physical address is generated. The physical address includes at least a die identifier. The read command generation information is input into the selector 62, which has two inputs and one output.

The write request is input into the buffer allocator 64 from the determiner 56. The buffer allocator 64 allocates the write buffer in the buffer area 14c in response to the write request. Subsequently, the controller 16 obtains write data from the host 2, and writes it into the write buffer. The layout allocator 68 determines the write destination physical address. The layout allocator 68 updates the logical/physical address conversion table 60 so as to associate the determined physical address with the LBA included in the write request. Write command generation information that includes at least the write request, identification information on the write buffer, and the write destination physical address is generated. The physical address includes at least a die identifier. The write command generation information is input into the selector 62.

The selector 62 transmits the read command generation information or the write command generation information to the command dispatcher 70, based on (1) the timing of performing addition of the read operation time, and the timing of addition of the write operation time, (2) the timing of determining which is longer between the read die time and the write die time, (3) the condition for suspending the write operation, (4) the condition for resuming the write operation, and the like. Accordingly, the ratio between the number of commands pertaining to read operations and the number of commands pertaining to write operations generated by the command dispatcher 70 can be adjusted to meet the customer demands.

The command dispatcher 70 generates a sense command and a data-out command with respect to each flash memory die D, based on the read command generation information. The command dispatcher 70 transmits the generated commands to the NAND flash memory 12 via the non-volatile memory I/F 24. The command dispatcher 70 generates a data-in command and a program command with respect to each flash memory die D, based on the write command generation information. The command dispatcher 70 transmits the generated commands to the NAND flash memory 12 via the non-volatile memory I/F 24.

The NAND flash memory 12 reads data from the target memory cell according to the sense command. The NAND flash memory 12 transfers the data to the controller 16 according to the data-out command. The NAND flash memory 12 obtains the write data from the controller 16 according to the data-in command. The NAND flash memory 12 writes the data into the target memory cell according to the program command.

Upon reception of a read request during the write operation, for example, the data-in operation or the program operation, the command dispatcher 70 may generate a suspend command, and subsequently generate the sense command and the data-out command. The command dispatcher 70 transmits the generated commands to the NAND flash memory 12 via the non-volatile memory I/F 24. The NAND flash memory 12 suspends the write operation according to the suspend command. The NAND flash memory 12 executes the sense operation according to the sense command, and executes the data-out operation according to the data-out command.

When the data-out operation is completed, the command dispatcher 70 generates a resume command. The command dispatcher 70 transmits the generated command to the NAND flash memory 12 via the non-volatile memory I/F 24. The NAND flash memory 12 resumes the write operation according to the resume command.

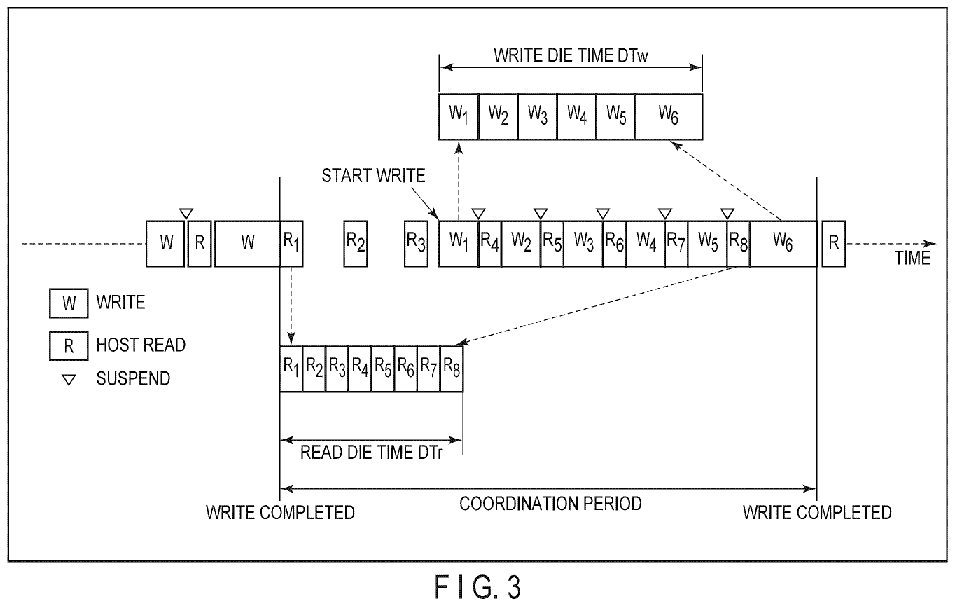

FIG. 3 is a diagram for illustrating an example of coordination of the read performance and the write performance by the coordinator 28a. The coordinator 28a has a write suspend function according to die time fairness. In FIG. 3, W represents the write operation time. In FIG. 3, W represents the operation time of a write operation (host write operation) executed in response to reception of a write request (host write request) from the host 2, or the operation time of a write operation due to a compaction operation (compaction write operation). The write operation time includes the command generation times of the data-in command and the program command, the data-in time, and the program time.

In FIG. 3, R represents the host read operation time. The host read operation is executed in response to reception of a read request (host read request) from the host 2. The host read operation time includes the command generation times of the sense command and the data-out command, the sense time, and the data-out time.

Each inverted triangle in FIG. 3 represents the suspend timing of the write operation.

As illustrated in FIG. 3, a coordination period is defined as a duration beginning on completion of a previous (e.g., the last) write operation (e.g., the most recently completed write operation) and ending upon completion of a current write operation. The controller 16 can recognize the completion of the program operation, i.e., the completion of the write operation, by issuing a status read command to the NAND flash memory 12, for example. Alternatively, a ready/busy signal output from the NAND flash memory 12 indicates a ready state, which allows the controller 16 to recognize the completion of the program operation. The coordinator 28a coordinates the read performance and the write performance in the coordination period.

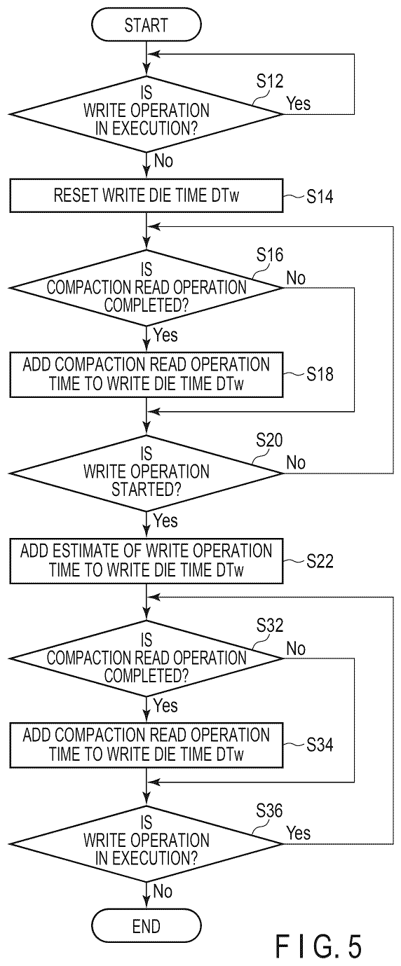

A write die time DTw includes a write operation time estimated when execution of one write operation is started. An example of a procedure of calculating the write die time DTw is described later with reference to FIG. 5.

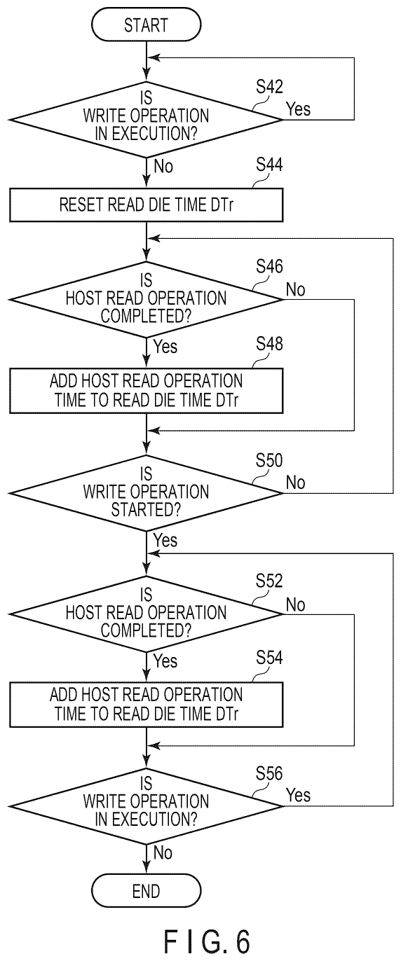

The read die time DTr is a cumulative total of time (actually measured values) of the host read operations. When one host read operation is completed, the time of the completed operation is accumulated in the read die time DTr. An example of a procedure of calculating the read die time DTr is described later with reference to FIG. 6.

When the host I/F 22 receives the host read request issued by the host 2 during the NAND flash memory 12 executing the write operation, the coordinator 28a performs determination pertaining to the die time. That is, the coordinator 28a compares the ratio Rrw (=DTr/DTw) of the read die time DTr to the write die time DTw in the coordination period, with a first value demanded by a customer.

The first value is set by, for example, the host 2. For example, in a case where the first value is 1.0, the coordinator 28 a suspends the write operation and executes the read operation so as to equalize the processing time pertaining to the read request and the processing time pertaining to the write request. In a case where the first value is 2.0, the coordinator 28a suspends the write operation and executes the read operation so as to make the processing time pertaining to the read request twice as long as the processing time pertaining to the write request. In a case where the first value is 0.5, the coordinator 28a suspends the write operation and executes the read operation so as to make the processing time pertaining to the read request half the processing time pertaining to the write request.

If the ratio Rrw is less than the first value, i.e., if the write die time DTw is relatively long, the coordinator 28a transmits the suspend command to the NAND flash memory 12, and causes the NAND flash memory 12 to suspend the write operation. The coordinator 28a causes the NAND flash memory 12 to execute the sense operation and the data-out operation that correspond to the received host read request. If the write operation is suspended and the read operation is performed as described above, the read die time DTr increases, and the ratio Rrw approaches the first value. Note that the write operation to be suspended may include the command generating operation. However, the time required for the command generating operation is short. Accordingly, the command generating operation is not necessarily regarded as a target of suspension.

If the ratio Rrw is the first value or higher, i.e., the read die time DTr is relatively long, the coordinator 28a transmits no suspend command to the NAND flash memory 12. In this coordination period, no write operation is suspended thereafter, and no host read operation is performed. As a result, the read die time DTr does not increase, and the ratio Rrw does not change.

FIG. 3 shows an example where the coordinator 28a receives three host read requests after the last write operation is completed and before the write request is received this time. The memory system 4 executes three host read operations R₁, R₂, and R₃ that respectively correspond to the three host read requests. The coordinator 28a calculates the cumulative total of time of the host read operations R₁, R₂, and R₃ as the read die time DTr.

Subsequently, the memory system 4 receives the write request, and starts the write operation. The coordinator 28a determines an estimated value of the time required to execute the write operation as the write die time DTw. Upon reception of a host read request during the write operation, the memory system 4 suspends the write operation and executes the host read operation if the ratio Rrw (=DTr/DTw) between the read die time DTr and the write die time DTw is less than the first value. In the example in FIG. 3, upon reception of the fourth host read request during the write operation in the coordination period, the memory system 4 suspends the write operation and executes the host read operation R₄. The write operation executed so far is represented as a sub-write operation W₁. The coordinator 28a adds the time of the host read operation R₄ to the read die time DTr. Upon completion of the host read operation R₄, the memory system 4 resumes the write operation. The herein resumed write operation is represented as a sub-write operation W₂.

Upon reception of the fifth host read request during the sub-write operation W₂ in the coordination period, the memory system 4 suspends the sub-write operation W₂ and executes the host read operation R₅. The coordinator 28a adds the time of the host read operation R₅ to the read die time DTr. Upon completion of the host read operation R₅, the memory system 4 resumes the write operation. The herein resumed write operation is represented as a sub-write operation W₃.

Upon reception of the sixth host read request during the sub-write operation W₃ in the coordination period, the memory system 4 suspends the sub-write operation W₃ and executes the host read operation R₆. The coordinator 28a adds the time of the host read operation R₆ to the read die time DTr. Upon completion of the host read operation R₆, the memory system 4 resumes the write operation. The herein resumed write operation is represented as a sub-write operation W₄.

Upon reception of the seventh host read request during the sub-write operation W₄ in the coordination period, the memory system 4 suspends the sub-write operation W₄ and executes the host read operation R₇. The coordinator 28a adds the time of the host read operation R₇ to the read die time DTr. Upon completion of the host read operation R₇, the memory system 4 resumes the write operation. The herein resumed write operation is represented as a sub-write operation W₅.

Upon reception of the eighth host read request during the sub-write operation W₅ in the coordination period, the memory system 4 suspends the sub-write operation W₅ and executes the host read operation R₈. The coordinator 28a adds the time of the host read operation R₈ to the read die time DTr. Upon completion of the host read operation R₈, the memory system 4 resumes the write operation. The herein resumed write operation is represented as a sub-write operation W₆.

It is assumed that by adding the time of the host read operation R₈, the ratio Rrw becomes the first value or higher. Subsequently, even if the memory system 4 receives a host read request during execution of the write operation, the memory system 4 does not suspend the write operation any more. That is, the memory system 4 continues execution of the sub-write operation W₆ until the write operation is completed.

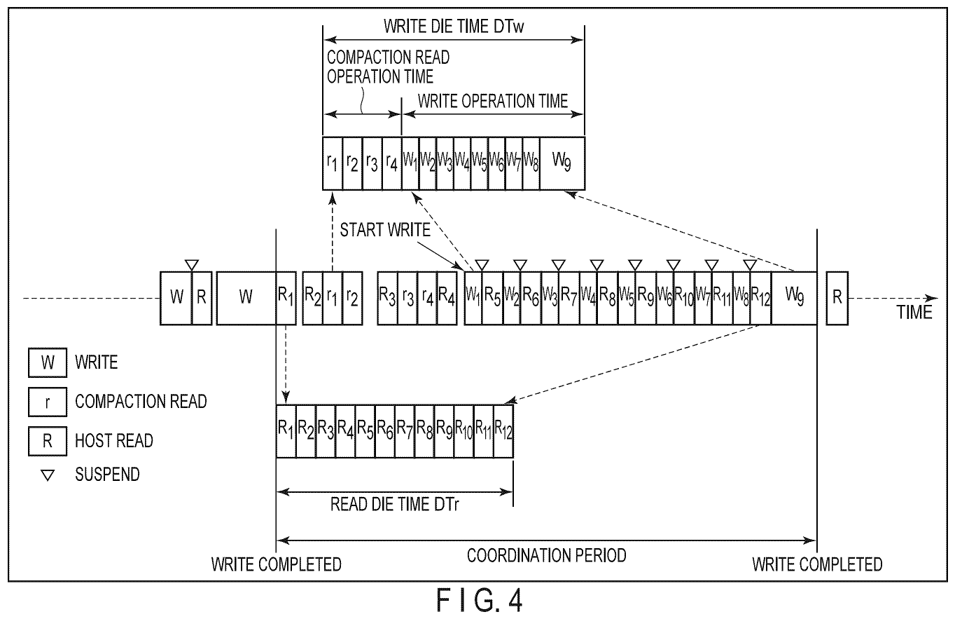

FIG. 4 is a diagram for illustrating another example of coordination of the read performance and the write performance by the coordinator 28a. Similar to FIG. 3, W in FIG. 4 represents the write operation time. Similar to FIG. 3, R in FIG. 4 represents the host read operation time. Further, r in FIG. 4 represents the compaction read operation time.

As described above, the read requests input into the coordinator 28a include the compaction read request generated by the CPU 28 besides the host read request. The write requests input into the coordinator 28a include the host write request transmitted from the host 2, and the compaction write request generated by the CPU 28.

The compaction read operation cooperates with the compaction write operation. Accordingly, as shown in FIG. 4, the coordinator 28a does not accumulate the time of the compaction read operation r as the read die time DTr, but adds it to the write die time DTw instead. That is, the write die time DTw is the sum of the cumulative total of the time of the compaction read operations (actually measured values), and the write operation time (the host write operation time or the compaction write operation time) estimated when the execution of one write operation (host write operation or compaction write operation) is started.

Also in the example in FIG. 4, similar to the example in FIG. 3, by regulating the number of suspensions during the write operation based on the ratio Rrw, the read performance and the write performance can be coordinated to meet the customer demands.

FIG. 4 shows an example where the coordinator 28a receives four host read requests and four compaction read requests after the last write operation is completed and before the write request is received this time. The memory system 4 executes four host read operations R₁, R₂, R₃, and R₄ and four compaction read operations r₁, r₂, r₃, and r₄ that respectively correspond to the four host read requests and the four compaction read requests. The coordinator 28a calculates the cumulative total of time of the host read operations R₁, R₂, R₃, and R₄ as the read die time DTr. An example of a procedure of calculating the read die time DTr is described later with reference to FIG. 6. The coordinator 28a calculates the cumulative total of time of the compaction read operations r₁, r₂, r₃, and r₄ as the write die time DTw. An example of a procedure of calculating the write die time DTw is described later with reference to FIG. 5.

Subsequently, the memory system 4 receives the write request, and starts the write operation. The coordinator 28a adds an estimated value of the time required to execute the write operation to the write die time DTw. Upon reception of a host read request during the write operation, the memory system 4 suspends the write operation and executes the host read operation if the ratio Rrw is less than the first value. In the example in FIG. 4, upon reception of the fifth host read request in the coordination period during the write operation, the memory system 4 suspends the write operation (sub-write operation W₁) and executes the host read operation R₅. The coordinator 28a adds the time of the host read operation R₅ to the read die time DTr. Upon completion of the host read operation R₅, the memory system 4 resumes the write operation (sub-write operation W₂). Likewise, the memory system 4 executes the sub-write operations W₂ to W₈ and the host read operations R₆ to R₁₂. The coordinator 28a adds the time of the host read operations R₆ to R₁₂ to the read die time DTr.

It is assumed that by adding the time of the host read operation R₁₂, the ratio Rrw becomes the first value or higher. Subsequently, even if the memory system 4 receives a host read request during the write operation, the memory system 4 does not suspend the write operation any more. That is, the memory system 4 continues execution of the sub-write operation W₉ until the write operation is completed.

Note that in the example shown in FIG. 4, no compaction read request is generated after the write operation in the coordination period is started. However, there is no limitation to this. If the compaction read request is generated, the coordinator 28a may suspend the write operation and execute the compaction read operation. In this case, the coordinator 28a may add the time of the executed compaction read operation to the write die time DTw.

FIGS. 5, 6, 7, and 8 are flowcharts for illustrating examples of procedures of coordinating the read performance and the write performance by the coordinator 28a. Before the coordinator 28a executes the coordination operation, the host 2 notifies the memory system 4 of a first value Ref to be compared with the ratio Rrw. The first value Ref is a ratio between the read operation time and the write operation time with respect to each flash memory die of the memory system 4 that the host 2 desires.

FIG. 5 is a flowchart for illustrating an example of a procedure of determining the write die time DTw by the coordinator 28a.

The coordinator 28a determines whether a write operation is in execution or not (step S12). This determination may be performed by issuing a status read command to the NAND flash memory 12, or checking a ready/busy signal output from the NAND flash memory 12. As shown in FIG. 3 or 4, in the case where one write operation includes a plurality of sub-write operations, it is determined that the write operation is executed until the final sub-write operation is completed. If the write operation is in execution (Yes in step S12), the coordinator 28a re-executes step S12.

If the write operation is not in execution (No in step S12), the coordinator 28a resets the write die time DTw (step S14). That is, when one write operation is completed, the write die time DTw is reset.

The coordinator 28a determines whether a compaction read operation is completed or not (step S16). This determination may be performed based on whether a completion response of the compaction read operation is received from the NAND flash memory 12 or not. If the compaction read operation is completed (Yes in step S16), the coordinator 28a adds the compaction read operation time to the write die time DTw (step S18). That is, if one compaction read operation is completed, the time of the completed operation is added to the write die time DTw as shown in FIG. 4. If the compaction read operation is not completed (No in step S16), the coordinator 28a does not execute step S18.

After step S18 or if the determination in step S16 is No, the coordinator 28a determines whether a write operation is started or not (step S20). This determination may be performed based on whether a write request has been received or not. If the write operation is not started (No in step S20), the coordinator 28a re-executes step S16. If the write operation is started (Yes in step S20), the coordinator 28a estimates the write operation time. As shown in FIG. 3 or 4, the coordinator 28a adds the estimate of the write operation time to the write die time DTw (step S22).

Subsequently, the coordinator 28a determines whether a compaction read operation is completed or not (step S32). If the compaction read operation is completed (Yes in step S32), the coordinator 28a adds the compaction read operation time to the write die time DTw (step S34). If the compaction read operation is not completed (No in step S32), the coordinator 28a does not execute step S34.

After step S34 or in the case of No in step S32, the coordinator 28a determines whether the write operation is in execution or not (step S36). If the write operation is in execution (Yes in step S36), the coordinator 28a re-executes step S32.

If the write operation is not in execution (No in step S36), the coordinator 28a finishes the process of determining the write die time DTw. As shown in FIG. 3, if no compaction read operation is executed in one coordination period, the write die time DTw is the write operation time estimated when the execution of the one write operation is started. As shown in FIG. 4, if one or more compaction read operations are performed in one coordination period, the write die time DTw is the sum of the write operation time estimated when the execution of the one write operation is started, and the cumulative total of the compaction read times.

Note that the controller 16 may execute no compaction read operation during a write operation. In this case, the coordinator 28a may omit the determination in steps S32 and S34.

FIG. 6 is a flowchart for illustrating an example of a procedure of determining the read die time DTr by the coordinator 28a.

The coordinator 28a determines whether a write operation is in execution or not (step S42). The determination in step S42 may be performed in a manner similar to that in step S12. If the write operation is in execution (Yes in step S42), the coordinator 28a re-executes step S42. Likewise, as shown in FIG. 3 or 4, in the case where one write operation includes a plurality of sub-write operations, it is determined that the write operation is executed until the final sub-write operation is completed. If the write operation is not in execution (No in step S42), the coordinator 28a resets the read die time DTr (step S44). That is, when one write operation is finished, the read die time DTr is reset.

The coordinator 28a determines whether a host read operation is completed or not (step S46). This determination may be performed based on whether the completion response of the host read operation is received from the NAND flash memory 12 or not. If the host read operation is completed (Yes in step S46), the coordinator 28a adds the host read operation time to the read die time DTr (step S48). If the host read operation is not completed (No in step S46), the coordinator 28a does not execute step S48.

After step S48 or if the determination in step S46 is No, the coordinator 28a determines whether a write operation is started or not (step S50). The determination in step S50 may be performed in a manner similar to that in step S20. If the write operation is not started (No in step S50), the coordinator 28a re-executes step S46.

After the write operation is started (Yes in step S50), the coordinator 28a determines whether a host read operation is completed or not (step S52). This host read operation may be, for example, a suspend read. The determination in step S52 may be performed in a manner similar to that in step S46. If the host read operation is completed (Yes in step S52), the coordinator 28a adds the host read operation time to the read die time DTr (step S54). If the host read operation is not completed (No in step S52), the coordinator 28a does not execute step S54.

After step S54 or if the determination in step S52 is No, the coordinator 28a determines whether the write operation started in step S50 is in execution or not (step S56). The determination in step S56 may be performed in a manner similar to that in step S12.

If the write operation is in execution (Yes in step S56), the coordinator 28a re-executes step S52. If the write operation is not in execution (No in step S56), the coordinator 28a finishes the process of determining the read die time DTr.

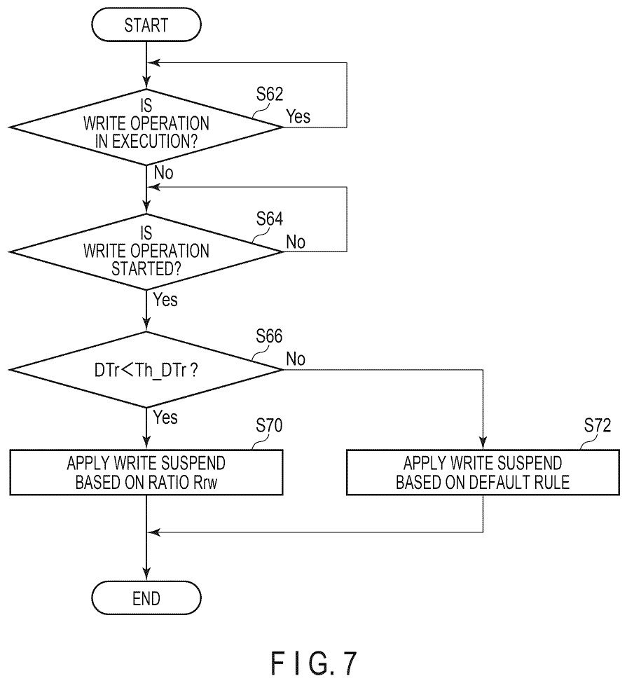

FIG. 7 is a flowchart for illustrating an example of a procedure of determining whether the coordinator 28a applies the write suspend function based on the ratio Rrw or not.

If many read operations are executed after the last write operation is completed and before the write operation is started this time, and the read die time DTr becomes long, it is conceivable that the write request is a throttled job, for example. In such a case, the controller 16 applies no write suspend function based on the ratio Rrw, but applies the write suspend function based on a default rule instead.

The coordinator 28a determines whether a write operation is in execution or not (step S62). The determination in step S62 may be performed in a manner similar to that in step S12. If the write operation is in execution (Yes in step S62), the coordinator 28a re-executes step S62.

If the write operation is not in execution (No in step S62), the coordinator 28a determines whether to start a write operation or not (step S64). The determination in step S64 may be performed in a manner similar to that in step S20. If the write operation is not started (No in step S64), the coordinator 28a re-executes step S64. If the write operation is started (Yes in step S64), the coordinator 28a determines whether the read die time DTr is shorter than a determination threshold Th_DTr or not (step S66). The determination threshold Th_DTr is a threshold for determining whether to apply the write suspend function based on the ratio Rrw or not.

If the read die time DTr is shorter than the determination threshold Th_DTr (Yes in step S66), the coordinator 28a determines to apply the write suspend function based on the ratio Rrw (step S70). If the read die time DTr is longer than or equal to the determination threshold Th_DTr (No in step S66), the coordinator 28a determines to apply the write suspend function based on the default rule (step S72).

An example of the write suspend function based on the default rule is to suspend a write operation if the number of write suspensions is smaller than an upper limit number set in the memory system 4, and to continue the write operation without suspending the write operation if the number of write suspensions is the upper limit number or larger. Another example of the write suspend function based on the default rule is to suspend a write operation if the cumulative total of the write suspend time is shorter than an upper limit time, and to continue the write operation without suspending the write operation if the write suspend time is the upper limit time or longer. After step S70 or S72, the processing is finished.

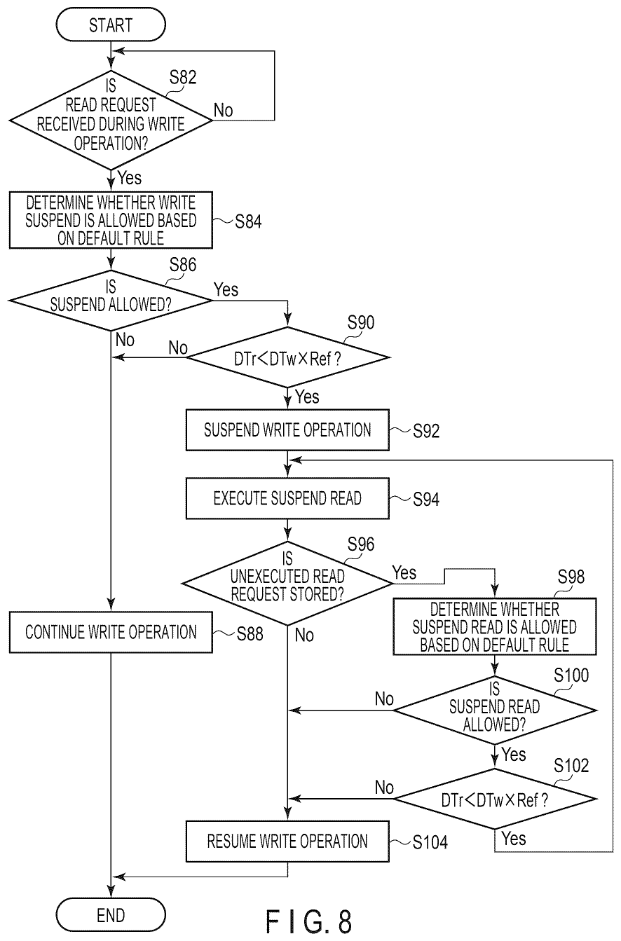

FIG. 8 is a flowchart for illustrating an example of a procedure of the write suspend by the coordinator 28a if it is determined to apply the write suspend function based on the ratio Rrw in step S70 as illustrated in FIG. 7.

The coordinator 28a determines whether a read request is received during execution of a write operation or not (step S82). The read request is the host read request or the compaction read request. If the read request is not received during execution of the write operation (No in step S82), the coordinator 28a re-executes the determination in step S82. If the read request is received during execution of the write operation (Yes in step S82), the coordinator 28a determines whether or not the write operation is allowed to be suspended based on the default rule (step S84). This is because the default rule is applied even if the write suspend function based on the ratio Rrw is applied. Note that the content of the determination in step S84 is the same as the content of the determination in step s66 described with reference to FIG. 7.

The coordinator 28a determines whether the write suspend is allowed or not based on the determination result of step S84 (step S86). The coordinator 28a determines that the write suspend is not allowed, if the number of write suspensions is the default upper limit number or larger and/or the cumulative total of the write suspend time is the default upper limit time or longer.

If the write suspend is not allowed (No in step S86), the coordinator 28a does not suspend the write operation and continues the write operation (step S88). The execution of the read request received in step S82 waits until the write operation is completed.

If the write suspend is allowed (Yes in step S86), the coordinator 28a determines whether or not the read die time DTr is shorter than the write die time DTw multiplied by the first value Ref (step S90). The fact of the read die time DTr being shorter the write die time DTw multiplied by the first value Ref indicates that the ratio Rrw (=DTr/DTw) is lower than the first value Ref. The first value Ref is the ratio between the read time and the write time per flash memory die that customers desire.

If the read die time DTr is longer than or equal to the write die time DTw multiplied by the first value Ref (No in step S90), the coordinator 28a does not suspend the write operation and continues the write operation (step S88). If the read die time DTr is shorter than the write die time DTw multiplied by the first value Ref (Yes in step S90), the coordinator 28a suspends the write operation (step S92). That is, the coordinator 28a transmits a suspend command to the NAND flash memory 12. The NAND flash memory 12 having received the suspend command suspends the write operation in execution.

The coordinator 28a executes the suspend read (step S94). That is, the coordinator 28a transmits a read command to the NAND flash memory 12. The NAND flash memory 12 having received the read command executes the read operation.

The coordinator 28a determines whether an unexecuted read request is stored or not (step S96). The coordinator 28a may determine whether a read request is stored in the submission queue or not. Alternatively, the coordinator 28a may determine whether a read request that has been fetched from the submission queue but has not been executed yet is stored in, for example, the volatile memory 14 or not.

If the unexecuted read request is stored (Yes in step S96), the coordinator 28a determines whether or not the suspend read is allowed based on the default rule (step S98). The content of the determination in step S98 is the same as the content of the determination in step S84.

The coordinator 28a determines whether the suspend read is allowed or not based on the determination result of step S98 (step S100). The coordinator 28a determines that the suspend read is not allowed, if the number of write suspensions is the default upper limit number or larger and/or the cumulative total of the write suspend time is the default upper limit time or longer.

If the suspend read is allowed (Yes in step S100), the coordinator 28a determines whether the read die time DTr is shorter than the write die time DTw multiplied by the first value Ref or not (step S102).

If the read die time DTr is shorter than the write die time DTw multiplied by the first value Ref (Yes in step S102), the coordinator 28a executes the suspend read (step S94). That is, the coordinator 28a transmits a read command to the NAND flash memory 12 so as to execute the unexecuted read request determined to be stored in step S96.

If an unexecuted read request is not stored (No in step S96), the suspend read is not allowed (No in step S100), or the read die time DTr is longer than or equal to the write die time DTw multiplied by the first value Ref (No in step S102), the coordinator 28a resumes the suspended write operation (step S104). That is, the coordinator 28a transmits a resume command to the NAND flash memory 12. The NAND flash memory 12 having received the resume command resumes the execution of the suspended write operation.

After step S88 or S104, the processing is finished.

If a read request occurs during execution of a write operation, the memory system 4 according to the embodiment suspends the write operation and executes the read operation. Accordingly, the execution of the read operation is not required to wait until the write operation is completed, and the ratio Rrw between the read die time DTr and the write die time DTw can be adjusted to a value desired by users.

If a considerable time elapses after the last write operation is completed and before the write operation is started this time, and a large number of read operations have already been executed when the write request occurs (No in step S66 in FIG. 7), the memory system 4 does not perform the coordination between the read performance and the write performance based on the ratio Rrw (see step S72 in FIG. 7). In this case, the write operation is suspended such that the number of write suspensions does not reach the default upper limit number and/or the cumulative total of the write suspend time does not reach the default upper limit time (see steps S84, S86, S98, and S100 in FIG. 8).

The memory system 4 according to the embodiment adjusts the read operation time and the write operation time, based on the read die time and the write die time in the coordination period after the last write operation is completed and before the write operation is completed this time. Consequently, the performances can be adjusted including the read requests having already been executed from the completion of the last write operation to the occurrence of the write request this time.

The coordinator 28a coordinates the performances, based on the read die time and the write die time in the coordination period. Accordingly, a buffer memory that has a large size and temporarily stores requests is not required.

If the suspendable condition (steps S86 and S90 in FIG. 8) is satisfied, the coordinator 28a suspends the write operation as shown in step S92 and executes the read request. Consequently, the latency of the memory system 4 is not degraded.

Note that it is assumed that the coordination period is from the completion of a previous (e.g., the last) write operation (e.g., the most recently completed write operation) until the completion of the write operation this time. However, it may be extended to that from the completion of a write operation that occurred several operations ago to the completion of the write operation this time.

If the number of read requests in a first coordination period is large and the read die time DTr in the first coordination period does not satisfy the suspendable condition (step S90 in FIG. 8), the suspendable condition for a second coordination period, which is the next to the first coordination period, may be changed. For example, if the read die time DTr in the first coordination period is longer than the write die time DTw multiplied by the first value Ref by a difference Δr and thus does not satisfy the suspendable condition, the suspendable condition for the second coordination period may be the read die time DTr is shorter than the write die time DTw multiplied by the first value Ref plus the difference Δr, that is, DTr<(DTw×Ref)+Δr. In other words, the determination condition for step S90 in the second coordination period may be DTr−Δr<(DTw×Ref). In other words, an exceeded time of the read operation time in the first coordination period may be subtracted from the read die time DTr in the second coordination period, thus making the suspendable condition for the second coordination period tend to be satisfied. Thus, if a measured read die time in the first coordination period exceeds a target read time by an excess amount, that excess amount may be subtracted from the measured read die time in a subsequent, second coordination period, thereby increasing the likelihood that a suspend condition in the second coordination period will be met.

The requests received by the coordinator 28a may include an erase request. Similar to the write operation, the erase operation takes time. Furthermore, a customer sometimes intends to set the ratio of the read operation time to the erase time. In this case, “write” in the above description is replaced with “erase”, thus allowing the read performance and the erase performance to be coordinated as described above.

For example, in the case of adjusting the ratio of the read operation time to the erase operation time, “write operation” in FIGS. 5, 6, 7, and 8 is changed to “erase operation”, “write operation time” is changed to “erase operation time”, “write die time” is changed to “erase die time”, and “write operation” is changed to “erase operation”.

Furthermore, the memory system 4 may respectively adjust the W/R ratio, and the ratio of the read operation time to the erase operation time to desired values.

While certain embodiments have been described, these embodiments have been presented by way of example only and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is

1. A memory system, comprising:
a non-volatile memory; and
a control circuit electrically connected to the non-volatile memory and configured to:
upon reception of a first read request issued from a host during a current write operation,
determine a first ratio of a first duration to a second duration, the first duration being an accumulated time of one or more read operations executed subsequent to completion of a most recently completed write operation and prior to completion of the current write operation, the second duration being a required time for the current write operation; and
determine whether to suspend the current write operation based on the first ratio.

2. The memory system of claim 1, wherein
the control circuit is further configured to:
compare the first ratio and a first value; and
determine whether to suspend the current write operation based on a result of the comparison.

3. The memory system of claim 2, wherein
the control circuit is configured to use a value designated by the host, as the first value.

4. The memory system of claim 2, wherein
the control circuit is configured to:
suspend the current write operation when the first ratio is lower than the first value; and
not suspend the current write operation when the first ratio is equal to or higher than the first value.

5. The memory system of claim 2, wherein
the control circuit is further configured to:
prior to performing the comparison, determine whether the first duration is shorter than a time threshold; and
perform the comparison between the first ratio and the first value only when the first duration is shorter than the time threshold.

6. The memory system of claim 5, wherein
the control circuit is further configured to determine whether to suspend the current write operation based on a default rule, when the first duration is not shorter than the time threshold.

7. The memory system of claim 6, wherein
the default rule permits suspending the current write operation only if a cumulative number of suspensions for the current write operation is smaller than a predetermined limit.

8. The memory system of claim 2, wherein
the control circuit is further configured to, if the first duration in a first coordination period exceeds the second duration multiplied by the first value by an excess amount, adjust the comparison for a subsequent second coordination period based on the excess amount.

9. The memory system of claim 8, wherein
the control circuit is configured to adjust the comparison for the subsequent second coordination period by subtracting the excess amount from an accumulated time of read operations in the subsequent second coordination period.

10. The memory system of claim 1, wherein
the control circuit is further configured to:
reset the first duration in response to the completion of the most recently completed write operation; and
determine, as the first duration, a cumulative total of operation times for the one or more read operations that correspond to one or more read requests received from the host.

11. The memory system of claim 10, wherein
the control circuit is further configured to:
reset the second duration in response to the completion of the most recently completed write operation; and
determine an estimate of the required time for the current write operation, as the second duration.

12. The memory system of claim 1, wherein
the control circuit is further configured to:
initiate a compaction operation including one or more compaction read operations;
determine a third duration that is an accumulated time of one or more compaction read operations executed after the most recently completed write operation is completed; and
determine whether to suspend the current write operation based on a second ratio of the first duration to a sum of the second and third durations.

13. The memory system of claim 1, wherein
the control circuit is further configured to, after suspending the current write operation and executing a read operation corresponding to the first read request, resume the current write operation.

14. The memory system of claim 13, wherein
the control circuit is further configured to determine whether to resume the current write operation based on whether an unexecuted read request is stored in a submission queue.

15. The memory system of claim 1, wherein
the control circuit is further configured to:
determine a third ratio using an accumulated time of one or more read operations executed subsequent to completion of a most recently completed erase operation and prior to completion of a current erase operation and a required time for the current erase operation; and
determine whether to suspend the current erase operation based on the third ratio.

16. A memory system, comprising:
a non-volatile memory that includes a plurality of memory dies; and
a control circuit electrically connected to the non-volatile memory and configured to:
upon reception of a first read request issued from a host,
determine a first memory die of the plurality of memory dies that is a target of the first read request, the first read request being received during a current write operation targeting the first memory die;
determine, for the first memory die, a first ratio of a first duration to a second duration, the first duration being an accumulated time of one or more read operations executed in the first memory die subsequent to a completion of a most recently completed write operation, the second duration being a required time for the current write operation in the first memory die; and
determine whether to suspend the current write operation, based on the first ratio.

17. A method of controlling a non-volatile memory, the method comprising:
receiving, a first read request from a host during a current write operation being executed in the non-volatile memory;
in response to receiving the first read request, determining a first ratio of a first duration to a second duration, the first duration being an accumulated time of one or more read operations executed subsequent to a completion of a most recently completed write operation, the second duration being a required time for the current write operation; and
determining whether to suspend the current write operation based on a comparison of the first ratio to a first value designated by the host.

18. The method of claim 17, further comprising:
determining that the first ratio is lower than the first value; and
in response to determining that the first ratio is lower than the first value, suspending the current write operation.

19. The method of claim 17, further comprising:
determining that the first ratio is equal to or higher than the first value; and
in response to determining that the first ratio is equal to or higher than the first value, continuing the current write operation.

20. The method of claim 17, further comprising:
initiating a compaction operation including one or more compaction read operations;
determining a third duration that is an accumulated time of one or more compaction read operations executed after the most recently completed write operation is completed; and
determining whether to suspend the current write operation based on a second ratio of the first duration to a sum of the second and third durations.
